(19) United States
(12) Patent Application Publication
(10) Pub. No.: US 2024/0177770 A1
(43) Pub. Date: May 30, 2024

(54) NON-VOLATILE MEMORY STRUCTURE WITH SINGLE CELL OR TWIN CELL SENSING

(71) Applicant: GlobalFoundries U.S. Inc., Malta, NY (US)

(72) Inventors: Bipul C. Paul, Mechanicville, NY (US); Chandrahasa Reddy Dinnipati, Bangalore (IN)

(21) Appl. No.: 18/058,992

(22) Filed: Nov. 28, 2022

(51) Int. Cl. G11C 13/00

(52) U.S. Cl. CPC G11C 13/004; G11C 13/0004; G11C 13/0026; G11C 2013/0042; G11C 2213/70

(57) ABSTRACT

A non-volatile memory (NVM) structure includes an array of memory cells. Within the array, data is stored in single cells or twin cells. The structure also includes switch circuits and sense amplifiers. Each switch circuit is connected between bitlines for a group of columns and a corresponding sense amplifier and establishes electrical connections to enable either single cell sensing or twin cell sensing. In single cell sensing, a data signal on a bitline connected to a memory cell is compared to a reference signal. In twin cell sensing, true and complement data signals on two bitlines connected to two memory cells are compared to each other. Since twin cell sensing compares true and complement data signals and does not require a reference signal, twin cell sensing is relatively accurate without the need for trim bits. Thus, the structure can store trim cells, accurately sense them, and subsequently use them.

### BACKGROUND

The present disclosure relates to non-volatile memory (NVM) structures and, more particularly, to embodiments of an NVM structure and a method of operating the structure.

Advantages of non-volatile memory (NVM) structures include, but are not limited to, and the ability to use periodic power down-power up cycles for reduced power consumption. However, such NVM structures often employ trim bits for accurate sensing operations and for other operations. Typically, the trim bits are stored externally, uploaded into an internal register, and then accessed from the register when necessary (e.g., during a sensing operation or other operation that requires trim bits). Registers are volatile memories and, thus, trim bit uploading from the external storage to the internal register is required each time the structure is powered on. Since trim bit uploading is time consuming, there is an inherent trade-off between power savings (e.g., by employing periodic power down-power up cycles) and performance (e.g., sensing speed or speed of other operations requiring trim bits). It would be advantageous to be able to store trim bits in the NVM structure itself to improve performance. However, as mentioned above, trim bits are for accurate sensing of data stored in the NVM memory structure. Therefore, if the trim bits are stored in NVM structure, they cannot be accurately read from the NVM structure.

### SUMMARY

Disclosed herein are embodiments of a non-volatile memory (NVM) structure. The NVM structure can include columns of memory cells and bitlines for the columns. Specifically, each bitline for a corresponding column can be connected to all of the memory cells in that corresponding column. The NVM structure can further include a sense amplifier and a switch circuit. The switch circuit can be electrically connected to the bitlines for a group of the columns and to the sense amplifier and can be selectively controlled to establish electrical connections that enable either single cell sensing by the sense amplifier or twin cell sensing by the sense amplifier.

In some embodiments, the NVM structure can include memory cells arranged in columns and rows and bitlines for the columns. Specifically, each bitline for a corresponding column can be connected to all of the memory cells in that corresponding column. The NVM structure can further include sense amplifiers for groups of the columns, respectively. The NVM structure can also include switch circuits for the same groups of the columns, respectively. Each switch circuit can be electrically connected to the bitlines for a corresponding group of the columns and to a corresponding sense amplifier. These switch circuits can be selectively controlled in order to establish electrical connections that enable any one of two different types of sensing operations by the sense amplifiers and, more particularly, that enable either single cell sensing or twin cell sensing by the sense amplifiers.

In some embodiments, the NVM structure can include memory cells arranged in columns and rows and bitlines for the columns. Specifically, each bitline can be connected to all of the memory cells in a corresponding column of the memory cells. The NVM structure can further include sense amplifiers for groups of the columns, respectively. The NVM structure can also include switch circuits for the same groups of the columns, respectively. Each switch circuit can be electrically connected to the bitlines for a corresponding group of the columns and to a corresponding sense amplifier. The NVM structure can further include a column decoder in communication with the switch circuits. The column decoder can outputs primary and secondary read mode enable signals to the switch circuits in order to selectively control the switch circuits. Specifically, depending upon the primary and secondary read mode enable signals received by the switch circuits, the switch circuits establish electrical connections to enable any one of two different types of sensing operations by the sense amplifiers and, particularly, enable either single cell sensing and twin cell sensing by the sense amplifiers.

### BRIEF DESCRIPTION OF THE DRAWINGS

The present disclosure will be better understood from the following detailed description with reference to the drawings, which are not necessarily drawn to scale and in which:

FIG. 1 is a schematic diagram illustrating embodiments of a disclosed NVM structure 100;

FIG. 2 is a schematic diagram illustrative of a resistive NVM cell that can be used for the memory cells in the NVM structure of FIG. 1;

FIGS. 3A-3B are cross-section diagrams illustrative of different resistance states of a magnetic tunnel junction (MTJ)-type programmable resistor that could be incorporated into the resistive NVM cell of FIG. 2;

FIGS. 4A-4B are cross-section diagrams illustrative of different resistance states of a phase change memory (PCM)-type programmable resistor that could be incorporated into the resistive NVM cell of FIG. 2;

FIGS. 5A-5B are cross-section diagrams illustrative of different resistance states of a resistive random access memory (RRAM)-type programmable resistor that could be incorporated into the resistive NVM cell of FIG. 2;

FIG. 6 is a schematic diagram illustrative of a threshold voltage (VT)-programmable transistor NVM cell that could be incorporated in to the NVM structure of FIG. 1;

FIG. 7 is a schematic diagram illustrative of a sense amplifier 170 that could be incorporated into the NVM structure of FIG. 1;

FIGS. 8A-8B are timing diagrams illustrating states of various signals during single cell sensing and twin cell sensing, respectively; and

FIG. 9 is a schematic diagram illustrative of column address decode logic that could be incorporated into the NVM structure of FIG. 1.

### DETAILED DESCRIPTION

As mentioned above, advantages associated with NVM structures include, but are not limited to, the ability to use periodic power down-power up cycles for reduced power consumption. However, such NVM structures often employ trim bits for accurate sensing operations and for other operations. Typically, the trim bits are stored externally, uploaded into an internal register, and then accessed from the register when necessary (e.g., during a sensing operation or other operation that requires trim bits). Registers are volatile memories and, thus, trim bit uploading from the external storage to the internal register is required each time the structure is powered on. Since trim bit uploading is time consuming, there is an inherent trade-off between power savings (e.g., by employing periodic power down-power up cycles) and performance (e.g., sensing speed or speed of other operations requiring trim bits). It would be advantageous to be able to store trim bits in the NVM structure itself to improve performance. However, as mentioned above, trim bits are for accurate sensing of data stored in the NVM memory structure. Therefore, if the trim bits are stored in NVM structure, they cannot be accurately read from the NVM structure.

In view of the foregoing disclosed herein are embodiments of an NVM structure including an array of memory cells arranged in columns and rows. Within the array, data can be stored in single cells or in twin cells. The structure can further include switch circuits and corresponding sense amplifiers. Each switch circuit can be connected between bitlines for a group of columns and a corresponding sense amplifier and can be configured to establish electrical connections to selectively enable two different types of sensing operations and, particularly, either single cell sensing or twin cell sensing. Single cell sensing refers to sensing where a data signal on a single bitline connected to a single memory cell is compared to a reference signal. Twin cell sensing refers to sensing where two data signals and, particularly, true and complement data signals on two bitlines connected to two memory cells (referred to herein as a twin cell) are compared to each other. Since twin cell sensing compares true and complement data signals (as opposed to a data signal to a reference signal), twin cell sensing is relatively accurate without the need for trim bits. Thus, the disclosed NVM structure could, for example, be used to store trim bits that would normally be stored external to the NVM structure (e.g., in a different block on the same chip or off-chip). Upon power up, the trim bits could be read out using twin cell sensing, loaded into an internal register, and accessed for subsequent structure operations (e.g., for fining tuning a gate bias voltage used by the sense amplifiers, as discussed below, or for some other operation).

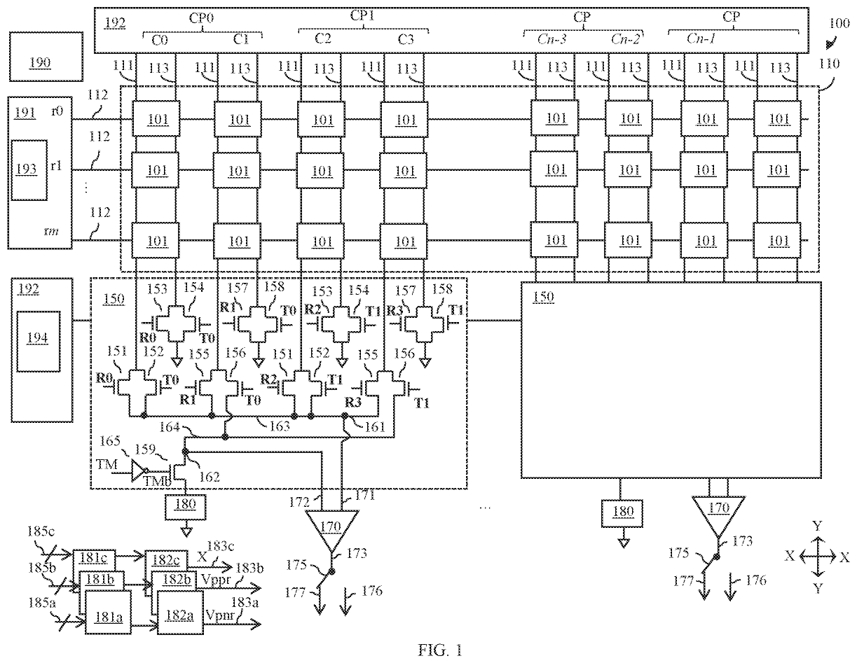

More particularly, referring to FIG. 1, disclosed herein are embodiments of an NVM structure 100. The NVM structure 100 can include an array 110 of memory cells 101. The memory cells 101 within the array 110 can be arranged in columns (e.g., see columns C0-Cn) and rows (e.g., see rows r0-rm). For purposes of illustration, the columns are shown on the drawing sheets as being oriented in the Y-direction and the rows are shown on the sheet as being oriented in the X-direction. The orientation of the columns and rows of the memory cells as shown in the figures is not intended to be limiting. Alternatively, the columns could be oriented in the X-direction and the rows could be oriented in the Y-direction. In any case, the columns can be essentially perpendicular to the rows with each memory cell 101 being located at an intersection between one column and one row (i.e., with each memory cell 101 being located within one specific column and one specific row).

The NVM structure 100 can further include bitlines 111 and source line 113 for the columns C0-Cn, respectively. All memory cells 101 in each column can be electrically connected between a source line 113 for the column and a bitline 111 for the same column. The NVM structure 100 can further include wordlines 112 for the rows r0-rm, respectively. All memory cells 101 in each row can be electrically connected to the wordline 112 for that row.

Within the NVM structure 100, the memory cells 101 in the array 110 can be, for example, NVM cells of a type having a bitline node, a source line node, and a gate node. For example, the memory cells 101 can be resistive non-volatile memory (NVM) cells (also referred to herein as resistance programmable NVM cells).

FIG. 2 is a schematic diagram illustrative of a resistive NVM cell that can be used for the memory cells 101 in the NVM structure 100 of FIG. 1. This resistive NVM cell can be in a specific column and a specific row within the array 110. The resistive NVM cell can include a programmable resistor 220 (also referred to herein as a variable resistor) and an access transistor 210 (e.g., an n-type field effect transistor (NFET)), which are connected in series between a bitline 111 for the specific column and a source line 113 for the same column. The programmable resistor 220 can have a first terminal 221 connected to the bitline 111 and a second terminal 222 opposite the first terminal 221. The access transistor 210 can have a drain region connected to the second terminal 222 of the programmable resistor 220, a source region connected to the source line 113 for the specific column, and a gate connected to a wordline 112 for the specific row.

The programmable resistor 220 in the resistive NVM of FIG. 2 can be any type of programmable resistor suitable for use in a resistive NVM cell. For example, the programmable resistor 220 could be a magnetic tunnel junction (MTJ)-type programmable resistor, a phase change memory (PCM)-type programmable resistor, or a resistive random access memory (RRAM)-type programmable resistor or any other suitable type of programmable resistor that is configured so that, by applying specific bias conditions to one or both terminals, the resistance of the resistor can be switched between at least two different stable resistance states. For example, the resistance state of such a programmable resistor can be changed to a high resistance state to store a first logic value or to a low resistance state to store a second logic value. The high resistance state can, for example, be programmed into the programmable resistor to store a logic value of “0”, whereas a low resistance state can be programmed into the programmable resistor to store a logic value of “1” or vice versa.

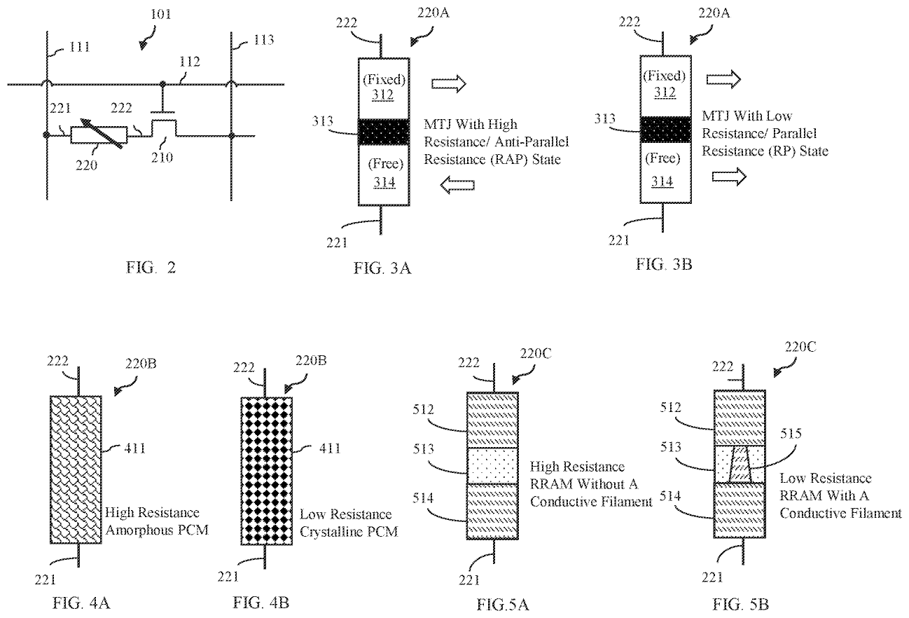

FIGS. 3A-3B are cross-section diagrams illustrative of different resistance states of an MTJ-type programmable resistor 220A (also referred to herein as an MTJ-type variable resistor) that could be incorporated into the resistive NVM cell of FIG. 2 (and, thus, used for memory cells 101 of the array 110 in the NVM structure 100). Such an MTJ-type programmable resistor 220A is typically a back end of the line (BEOL) multi-layer structure, which includes a free ferromagnetic layer 314 (also referred to as a switchable layer) at the first terminal 221, a fixed ferromagnetic layer 312 (also referred to as a pinned layer) at the second terminal 222, and a thin dielectric layer 313 (e.g., a thin oxide layer) between the free ferromagnetic layer 314 and the fixed ferromagnetic layer 312. Depending upon the biasing conditions on the first terminal 221 and the second terminal 222 during a write operation, the MTJ-type programmable resistor 220A exhibits different resistances (e.g., a low resistance or a high resistance that is higher than the low resistance). For example, during a write operation, a high positive voltage (VDD) can be applied to the second terminal 222 and the first terminal 221 can be discharged to ground (e.g., at 0V). In this case, current flow through the device causes the free ferromagnetic layer 314 to switch to (or maintain) the anti-parallel resistance (RAP) state (also referred to as a high resistance state), thereby storing the first logic value (e.g., a logic value of “0”) (see FIG. 3A). Alternatively, during the write operation, VDD can be applied to the first terminal 221 and the second terminal 222 can be discharged to ground (e.g., at 0V). In this case, current flow through the device causes the free ferromagnetic layer 314 to switch to (or maintain) a parallel resistance (RP) state (also referred as a low resistance state), thereby storing the second logic value (e.g., a logic value “1”) (see FIG. 3B).

FIGS. 4A-4B are cross-section diagrams illustrative of different resistance states of a PCM-type programmable resistor 220B (also referred to herein as a PCM-type variable resistor) that could be incorporated into the resistive NVM cell of FIG. 2 (and, thus, used for the memory cells 101 in the array 110 of the NVM structure 100). Such a PCM-type programmable resistor employs a phase change material 411 (e.g., a chalcogenide compound) with programmable structural phases that exhibit different resistances (e.g., a low resistance crystalline phase and a high resistance amorphous phase). Switching of the structural phase is dependent upon the local temperature, which is controlled by the length and strength of an applied voltage. For example, switching from a crystalline phase (i.e., a low resistance state) to an amorphous phase (i.e., a high resistance state) to store the first logic value (e.g., a logic value of “0”) can be achieved by applying a short high voltage pulse to one or both terminals 221-222 to quickly heat the phase change material above its melting point (see FIG. 4A). Switching from the amorphous phase to the crystalline phase to store the second logic value (e.g., a logic value of “1”) can be achieved by applying a longer lower voltage pulse to one or both terminals 221-222 to heat the phase change material to its crystallization temperature and then allowing it to cool (see FIG. 4B).

FIGS. 5A-5B are cross-section diagrams illustrative of different resistance states of a RRAM-type programmable resistor 220C that could be incorporated into a resistive NVM cell of FIG. 2 (and, thus, used for the memory cells 101 in the array 110 of the NVM structure 100). Such an RRAM-type programmable resistor is typically a back end of the line (BEOL) multi-layered structure, which includes two metallic layers 512 and 514 separated by a dielectric region 513 (also referred to herein as a resistance switching region). Depending upon the specific materials used and on the biasing conditions applied to the opposing end terminals 221-222 of such a resistor during a write operation, metal ions migrate to: (a) grow conductive filament(s) 515 in the dielectric region 513 extending between the metallic layers 512 and 514 so that the resistance state of the RRAM-type programmable resistor decreases or (b) break down conductive filament(s) within the dielectric region 513 between the metallic layers 512 and 514 so that the resistance state of the RRAM-type programmable resistor increases. Those skilled in the art will recognize that the total number of stable resistance states achievable with such an RRAM-type programmable resistor can vary depending upon the materials used and the biasing conditions. An RRAM-type programmable resistor could include metallic layers 512-514 (e.g., of platinum (Pt), titanium (Ti), titanium nitride (TiN), etc.) and, between the metallic layers 512-514, a dielectric region 513 including an oxide layer, such as a tantalum oxide (Ta2O5) layer, a hafnium oxide (HfO2) layer, an iron oxide (Fe2O3) layer, a titanium oxide (TiO2) layer, etc. However, the addition of one or more thin interface barrier layers (e.g., a second oxide layer, such as aluminum oxide (Al₂O₃) or some other oxide layer, an amorphous silicon layer, or some other suitable interface barrier layer) between the oxide layer and one or both metallic layers can improve the switching characteristics and increase the number of different detectable stable resistance states between a minimum resistance state and a maximum resistance state.

Alternatively, the memory cells 101 could be NVM cells of any other type with a bitline node, a source line node and a gate node.

For example, the memory cells 101 could be threshold voltage (VT)-programmable transistor NVM cells.

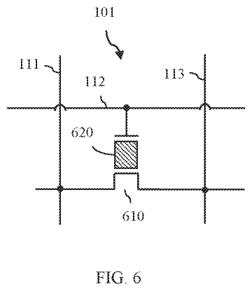

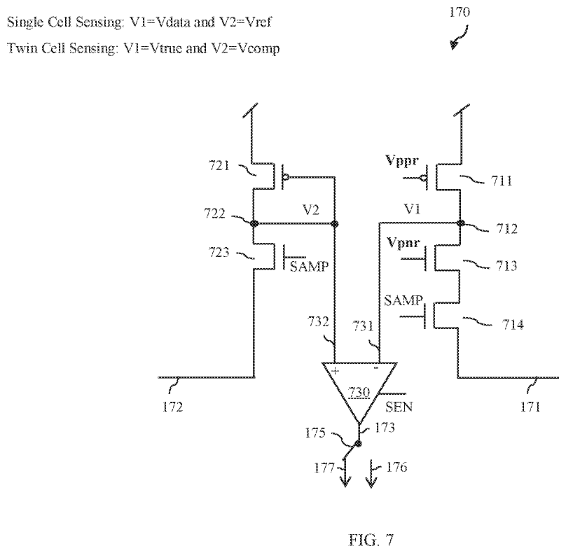

FIG. 6 is a schematic diagram illustrative of a VT-programmable transistor NVM cell that could be used for the memory cells 101 in the array 110 of the NVM structure 100. The VT-programmable transistor NVM cell can be located at a specific column and a specific row and can include a VT-programmable FET 610 (e.g., a VT-programmable NFET). The VT-programmable FET can include: a gate 620, which is electrically connected to the wordline 112 for the specific row; a drain region, which is electrically connected to the bitline 111 for the specific column; and a source region, which is electrically connected to the source line 113 for the specific column. The gate 620 can be configured so that, depending upon biasing conditions applied to the gate, source and drain terminals, the VT of the transistor can be selectively programmed (i.e., changed) and, more particularly, the VT can be switched between a high-VT state, where the transistor is more resistive, to store the first logic value (e.g., a logic value of “0”) and a low-VT state, where the transistor is less resistive/more conductive, to store the second logic value (e.g., a logic value of “1”). Thus, the gate 620 can effectively function as a data storage node. VT-programmable FETs include, but are not limited to, charge trap field effect transistors (CTFETs), ferroelectric field effect transistors (FeFETs), and floating gate field effect transistors (FGFETs). Such VT-programmable FETs are well known in the art and, thus, the details thereof are omitted from this specification in order to allow the reader to focus on the salient aspects of the disclosed embodiments.

Referring again to FIG. 1, the NVM structure 100 can further include a controller 190 and peripheral circuitry 191-193 in communication with the controller 190, connected to the bitlines 111, source lines 113, and word lines 112 of the array 110 and configured to facilitate memory cell operations (e.g., write and read) in response to various signals (as discussed in greater detail below) from the controller 190. The peripheral circuitry can include a row control block 191, which is electrically connected to the WLs 112 for the rows, and which includes, for example, row address decode logic 193 and wordline drivers for appropriately biasing specific wordlines depending upon the type of memory cell and the mode of operation. The peripheral circuitry can also include at least one column control block 192, which is connected to the bitlines 111 and source lines 113 for the columns and which includes, for example, column address decode logic 194 (which is uniquely configured, as discussed in detail below, to generate both primary and secondary read mode enable signals that, in combination, cause switch circuits to selectively enable two different types of sensing operations and, particularly, either single cell sensing or twin cell sensing operations), bitline drivers and source line drivers for appropriately biasing specific bitlines and source lines depending upon the type of memory cell, the mode of operation, etc. Generally, except for the novel features of the disclosed embodiments related to the column address decode logic 194, the peripheral circuitry features mentioned above are well known in the art and, thus, the details thereof have been omitted from the specification to allow the reader to focus on the salient aspects of the disclosed embodiments.

Write operations can include writing data bits to the memory cells. Read operations can include sensing stored data. As mentioned above, the structure enables different types of sensing operations including both single cell sensing and twin cell sensing. Thus, for example, within the array a data value can be written to in a single memory cell and to read out this data value a single cell sensing operation can include comparing a data signal from that single memory cell to a reference signal. Additionally, within the array, true and complement data bits can be written to a pair of memory cells (referred to as a twin cell) and to read out the stored data value a twin cell sensing operation can include comparing a true data signal from one memory cell of the pair to a complement data signal from another memory cell of the pair. In any case, the same write schemes can be used to write 1s and 0s into any of the memory cells within the array, regardless of whether they are storing a single data bit (for signal cell sensing) or a true or complement data bit (for twin cell sensing). Various write schemes are well known in the art and, thus, the details thereof have been omitted from this specification in order to allow the reader to focus on the salient aspects of the disclosed embodiments. However, as discussed above with regard to FIGS. 2-6, the write schemes will vary depending upon the specific type of memory cell.

The NVM structure 100 can further include: switch circuits 150; sense amplifiers 170, wherein each switch circuit 150 is connected between a corresponding group of the columns of memory cells within the array 110 and a corresponding sense amplifier 170; and reference generators 180 for the sense amplifiers 170, respectively.

More particularly, each reference generator 180 can be, for example, a resistor. This resistor can, by design, have a resistance that is approximately mid-way between the different resistances of the memory cells 101 depending upon whether they are programmed to be in either the low resistance state or a high resistance state. The resistor can be a fixed resistor preselected to have such a resistance. Alternatively, the resistor can be a programmable resistor programmed to have such a resistance.

FIG. 7 is a schematic diagram illustrative of a sense amplifier 170 that could be incorporated into the NVM structure 100. The sense amplifier 170 can include a differential amplifier 730. The differential amplifier 730 can include an inverting input 731, a non-inverting input 732, and an output 173 (which is also the output of the sense amplifier 170 itself). The sense amplifier 170 can further include a first branch (also referred to herein as a data branch) including a P-channel field effect transistor (PFET) 711, and two N-channel field effect transistors (NFETs) 713-714 connected in series between a positive voltage rail (e.g., VDD) and the first input 171 to the sense amplifier 170. The inverting input 731 of the differential amplifier 730 can be connected to the junction 712 between the PFET 711 and NFET 713. The sense amplifier 170 can further include a second branch (also referred to herein as a reference branch) in parallel with the first branch and including a PFET 721 and an NFET 723 connected in series between the positive voltage rail (e.g., VDD) and the second input 172 to the sense amplifier 170. The non-inverting input 732 of the differential amplifier 730 and the gate of the PFET 721 can both be connected to the junction 722 between the PFET 721 and NFET 723. Within the sense amplifier 170, the NFET 714 and the NFET 723 can be controlled by a common control signal (SAMP). That is, the gates of these two NFETs can both be connected to receive SAMP. Additionally, within the first branch, the PFET 711 and the NFET 713 can be controlled by corresponding gate bias voltages (Vppr and Vpnr, respectively). Specifically, the PFET 711 can have a gate connected to receive a first gate bias voltage (Vppr) and the NFET 713 can have a gate connected to receive a second gate bias voltage (Vpnr). Vpnr and/or Vppr can, for example, be generated and output by on-chip bias voltage generation circuit(s) 182a and/or 182b. The state of the differential amplifier 730 can be controlled by a sense enable signal (SEN) (e.g., from controller 190). In operation, when SEN is low, the differential amplifier 730 can be in a standby mode. When SEN is high, the differential amplifier 730 can be in an operational mode, can compare a first voltage (V1) at the inverting input 731 to a second voltage (V2) at the non-inverting input 732, and can output a digital output (Dout) at the output 173 based on the difference between the two inputs. If V1>V2, Dout will be low, whereas if V2>V1, Dout will be high.

Each group of the columns of the memory cells in the array 110 can include some even number z of two or more columns. Furthermore, within each group, the columns can be organized into pairs of adjacent columns (referred to herein as a column pair) with each column pair including a first column (with all first memory cells therein connected between a first bitline and a first source line) and a second column (with all second memory cells therein connected between a second bitline and a second source line). For purposes of illustration, FIG. 1 shows each group of columns within the array including four columns and, thus, two column pairs. For example, the first group of columns of memory cells within the array 110 includes columns C0-C3 organized into two column pairs CP0 and CP1, and so on. However, it should be understood that the figures are not intended to be limiting. Alternatively, each group of columns can include any other even number z (e.g., 2, 4, 6, 8, etc.) of columns organized into z/2 column pairs.

Each switch circuit 150 within the NVM structure 100 can be in communication with the column control block 192 and, particularly, with the column address decode logic 194 (as discussed in greater detail below). Each switch circuit 150 can further be associated with a corresponding group of columns. Specifically, each switch circuit 150 can include multiple input nodes including: first input nodes electrically connected to the bitlines 111 for all z columns in a corresponding group of columns; second input nodes electrically connected to the source lines 113 for all z columns in the corresponding group; and an additional input node electrically connected to a reference generator 180 (as discussed in greater detail below). Each switch circuit 150 can further have a first output node 161 electrically connected to a first input 171 of the corresponding sense amplifier 170 and a second output node 162 electrically connected to a second input 172 of the corresponding sense amplifier 170.

Each switch circuit 150 can further be configured (as discussed in greater detail below) to establish electrical connections that selectively enable either single cell sensing by a corresponding sense amplifier 170 or twin cell sensing by the same corresponding sense amplifier 170. Single cell sensing refers to sensing, by a corresponding sense amplifier, of a data value stored in a single memory cell in a single column of a corresponding group of columns by comparing a data signal from the bitline for the single column to a reference signal. Twin cell sensing refers to sensing, by the corresponding sense amplifier, of a data value stored in two memory cells in two columns, respectively, of a pair of columns (i.e., of a column pair) in the corresponding group by comparing a true data signal from a first bitline for a first column of the column pair to a complement data signal from a second bitline for a second column of the column pair.

More particularly, each switch circuit 150 can include a first sense line 163 and a second sense line 164. The first output node 161 (which is electrically connected to the first input 171 of a corresponding sense amplifier 170) can be on or electrically connected to this first sense line 163. The second output node 162 (which is electrically connected to the second input 172 of the corresponding sense amplifier 170) can be on or electrically connected to the second sense line 164. Each switch circuit 150 can further include multiple switches. For each pair of columns (i.e., for each column pair) within the corresponding group of columns associated within the switch circuit 150, the switch circuit 150 can include eight switches. First and second switches 151-152 (e.g., first and second NFET) can be connected in parallel between the first bitline 111 for the first column of each column pair and the first sense line 163. Third and fourth switches 153-154 (e.g., third and fourth NFETs) can be connected in parallel between the first source line 113 for the first column of each column pair and ground. A fifth switch 155 (e.g., fifth NFET) can be connected between the second bitline 111 of the second column of each column pair and the first sense line 163. A sixth switch 156 (e.g., a sixth NFET) can be connected between the second bitline 111 of the second column of each column pair and the second sense line 164. Seventh and eighth switches 157-158 (e.g., seventh and eighth NFETs) can be connected in parallel between the second source line 113 of the second column of each column pair and ground.

For each column pair (CP0, CP1, etc.), the first switch 151, the third switch 153, the fifth switch 155 and the seventh switch 157 can be controlled by primary read mode enable signals (rden signals, which are indicated simply as R signals in FIG. 1 to avoid clutter) and the primary read mode enable signals can be column-specific. For example, as illustrated, rden0 (R0) controls the first switch 151 and third switch 153 connected to the bitline 111 and the source line 113, respectively, of column C0, rden1 (R1) controls the fifth switch 155 and the seventh switch 157 connected to the bitline 111 and the source line 113, respectively, of column C1, rden2 (R2) controls the first switch 151 and third switch 153 connected to the bitline 111 and the source line 113, respectively, of column C2, rden3 (R3) controls the fifth switch 155 and the seventh switch 157 connected to the bitline 111 and the source line 113, respectively, of column C3, and so on.

Additionally, for each column pair (CP0, CP1, etc.), the second switch 152, the fourth switch 154, the sixth switch 156 and the eighth switch 158 can be controlled by secondary read mode enable signals (also referred to herein as trim enable signals or Trim_en signals, which are indicated simply as T signals in FIG. 1 to avoid clutter) and the secondary read mode enable signals can be column pair-specific. For example, as illustrated, Trim_en0 (T0) controls the second switch 152 and fourth switch 154 connected to the bitline 111 and the source line 113, respectively, of column C0 of column pair CP0 as well as the sixth switch 156 and the eighth switch 158 connected to the bitline 111 and the source line 113, respectively, of column C1 of CP0, Trim_en1 (T1) controls the second switch 152 and fourth switch 154 connected to the bitline 111 and the source line 113, respectively, of column C2 of CP1 as well as the sixth switch 156 and the eighth switch 158 connected to the bitline 111 and the source line 113, respectively, of column C3 of CP1, and so on.

Finally, each switch circuit 150 can further include one additional switch 159 (e.g., an additional NFET) connected between the additional input node (and thereby the corresponding reference generator 180) and the second output node 162. The additional switch 159 can be controlled by an additional enable signal. For example, each switch circuit 150 can further include an inverter 165 with an output connected to the gate of the additional switch 159. TM (also referred to as a global trim bit enable signal) can be applied to the input of the inverter 165 and TMb can be the additional enable signal applied to the gate of the additional switch 159.

As mentioned above, all of the switches 151-155 can be NFETs. Therefore, when the enable signal applied to the gate of the NFET is high, the NFET will be turned on. When the enable signal applied to the gate of the NFET is low, the NFET will be turned off.

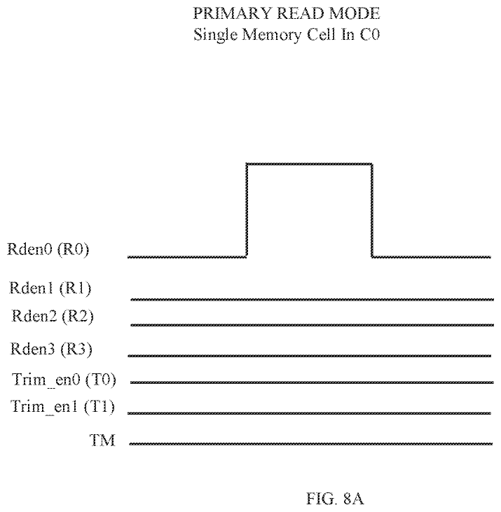

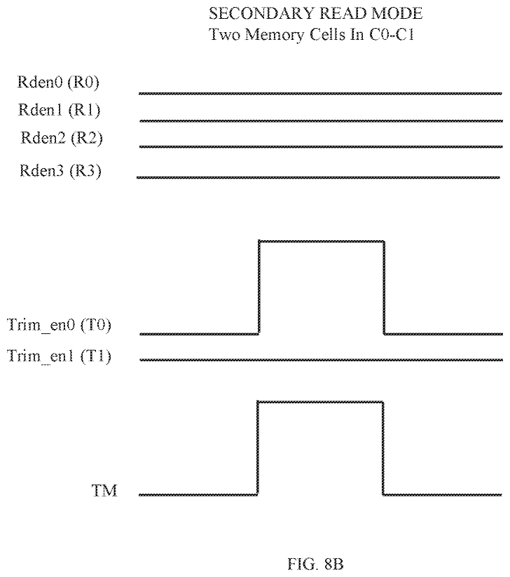

FIGS. 8A-8B are timing diagrams illustrating how such a switch circuit 150 can be employed to selectively enable either single cell sensing or twin cell sensing.

Specifically, FIG. 8A is a timing diagram illustrating the primary read mode enable signals R0-R3 and the secondary read mode enable signals T0-T1 received by a switch circuit 150, which is associated columns C0-C3, during single cell sensing directed to the single memory cell 101 located at row r1 and column C0. A data bit is stored in the single memory cell. WL 112 for r1 switches to high, R0 goes high, and R1, R2, R3, T0, T1 and TM all remain low. Thus, TMb from the inverter 165 goes high and the additional switch 159 turns on. Additionally, the first switch 151 and the third switch 153 for C0 turn on and all other switches turn off. As a result, the data signal on the bitline111 of C0 is transmitted to the first sense line 163 and the first output node 161 and is, thus, applied to the first input 171 of the sense amplifier 170. Furthermore, the reference generator 180 is connected to the second output node 162 and only the reference signal (e.g., Iref) from the reference generator 180 is transmitted to the second output node 162 and is, thus, applied to the second input 172 of the sense amplifier 170. Referring again to FIG. 7 in combination with FIGS. 1 and 8A, during this single cell sensing process, SEN and SAMP will go high so that NFET 723 is switched on. Thus, V2 (which is Vref during single cell celling) on node 722 is pulled down through NFET 723 and through additional switch 159. The pull-down of V2 is limited by the resistance of the resistor/reference generator 180 and by the PFET 721 (which will exhibit increased conductivity and pull up V2 if it drops too low). The pull-down of V1 at the junction 712 will depend on the resistance state of the selected memory cell (given Vpnr and Vppr). As discussed above, if the single cell is in a high resistance state, V1>V2 and Dout will be low, whereas if the single cell is in a low resistance state, V2>V1 and Dout will be high.

FIG. 8B is a timing diagram illustrating the primary read mode enable signals R0-R3 and the secondary read mode enable signals T0-T1 received by the same switch circuit 150, which is associated with columns C0-C3, during twin cell sensing directed to two memory cells of a twin cell located at row rm and column pair CP0 (i.e., C0 and C1). In this case, the twin cell includes a first memory cell, which stores a true data bit, located at rm and C0 and a second memory cell, which stores a complement data bit, located at rm and C1. WL 112 for rm switches to high, T0 switches to high, TM switches to high, and R0-R3 and T2 all remain low. Thus, TMb from the inverter 165 goes low. As a result, within this switch circuit, the second switch 152 and the fourth switch 154 of C0 and the sixth switch 156 and the eighth switch 158 for C1 turn on and all other switches including the additional switch 159 turn off. Thus, the reference generator 180 is disconnected from the second output node 162, a true data signal from the bitline 111 of C0 at the first output node 161 is applied to the first input 171 of the sense amplifier 170, and a complement data signal from the bitline 111 of C1 at the second output node 162 is applied to the second input 172 of the sense amplifier 170. Referring to FIG. 7 in combination with FIGS. 1 and 8B, during this twin cell sensing process, SEN and SAMP will go high so that NFET 723 is switched on. Thus, V2 (which is Vcomplement and indicative of the complement data bit during twin cell sensing) on node 722 is pulled down through NFET 723 and through additional switch 159. The pull-down of V2 is limited by the resistance state of the second memory cell at rm and C1 and by the PFET 721 (which will exhibit increased conductivity and pull up V2 if it drops too low). The pull-down of V1 (which is Vtrue and indicative of the true data bit during twin cell sensing) at node 712 will depend on the resistance state of the first memory cell at rm and C0. As discussed above, if the first memory cell is in a high resistance state, V1>V2 and Dout will be low, whereas if the first memory cell is in a low resistance state, V2>V1 and Dout will be high.

As mentioned above, the column address decode logic 194 for the disclosed NVM structure 100 is uniquely configured to generate both primary and secondary read mode enable signals that, in combination, cause the switch circuits to selectively enable the single cell sensing or twin cell sensing operations described above.

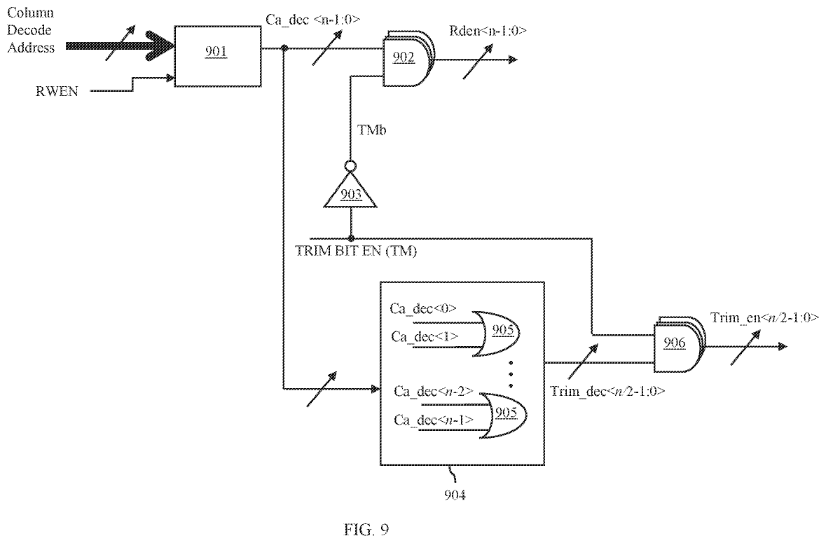

FIG. 9 is a schematic diagram illustrative of column address decode logic 194 that can be incorporated into the disclosed NVM structure 100. As illustrated, this column address decode logic 194 can include a column decoder 901. The column decoder 901 can be a conventional column decoder, which receives a specific column decode address and which outputs primary column address decode signals for the columns, respectively (e.g., Ca_dec<n−1:0>), one of which will be high indicating the selected column specified by the received column decode address.

The column address decode logic 194 can further include first AND gates 902 (one for each column), an inverter 903, a column pair decoder 904, and second AND gates 906 (one for each column pair). The inverter 903 can be connected to receive the global trim bit enable signal (TM), as an input, and to output an inverted global trim bit enable signal (TMb) as an output.

The first NAND gates 902 can be connected to receive their respective Ca_dec<n−1:0> from the column decoder 901 and TMb from the inverter 903, as inputs, and can output a corresponding primary read mode enable signal (e.g., Rden<n−1:0>). Given the AND gate truth table, the output Rden<n−1:0> of any given first AND gate 902 will be as follows: if TMb is high (i.e., TM is low) and the received Ca_dec<n−1:0> is high, the output Rden<n−1:0> will be high and single-cell sensing of a memory cell in the selected column can be performed; if TMb is high and the received Ca_dec<n−1:0> is low, the output Rden<n−1:0> will be low so single cell sensing of a memory cell in the column at issue will not be performed; and if TMb is low, the output Rden<n−1:0> will be low regardless of the received Ca_dec<n−1:0> so single cell sensing will not be directed to any single memory cell in any of the columns.

The column pair decoder 904 be connected to receive all Ca_dec<n−1:0> and can include multiple OR gates 905 for corresponding columns pairs. Each OR gate 905 will receive, receive, as inputs, the two column address decode signals for the two columns in the corresponding column and will output a corresponding column pair address decode signals for the corresponding column pair (e.g., Trim_dec<n/2−1:>). Given the OR gate truth table, if both inputs to an OR gate 905 are low, the output Trim_dec<n/2−1:> will be low, otherwise it will be high.

The second NAND gates 906 can be connected to receive their respective Trim_dec<n/2−1:0> from the column pair decoder 904 and TM, as inputs, and can output a corresponding secondary read mode enable signal (e.g., Trim_en<n/2−1:0>). Given the AND gate truth table, the output Trim_en<n/2−1:0> of any given second AND gate 906 will be as follows: if TM is high (i.e., TMb is low) and the received Trim_dec<n/2−1:0> is high, the output Trim_en<n/2−1:0> will be high and twin-cell sensing of a twin cell (i.e., a pair of memory cells) in the selected column pair can be performed; if TM is high and the received Trim_dec<n/2−1:0> is low, the output Trim_en<n/2−1:0> will be low so twin cell sensing of memory cells in the column pair at issue will not be performed; and if TM is low, the output Trim_en<n−1:0> will be low regardless of the received Trim_dec<n−1:0> so twin cell sensing will not be directed to any of the twin cells in any of the column pairs.

Since the twin cell sensing performed by the NVM structure 100 described above compares true and complement data signals as opposed to a data signal to a reference signal, it is relatively accurate without the need for multi-bit trim signals to adjust the voltage levels of Vpnr and Vppr, respectively, supplied to the sense amplifiers 170 during sensing. Instead, nominal Vpnr and Vppr levels can be used. Thus, the disclosed NVM structure 100 could be used to store trim bits of multi-bit trim signals that would normally be stored external to the NVM structure 100 (e.g., in a different block on the same chip or off-chip) because they could not be accurately sensed without adjusting Vpnr and/or Vppr.

More particularly, the NVM structure 100 disclosed herein can further include one or more additional components 182a-182c, which are connected to one or more register(s) 181a-181c, respectively. Each additional component 182a-182c can be configured to receive a particular multi-bit trim signal 185a-185c from a corresponding register 181a-181c and to generate and output an adjustable output 183a-183c, respectively, based on that particular multi-bit trim signal 185a-185c. The adjustable output 183a-183c can, for example, be a voltage or other parameter employed by the NVM structure 100 during subsequent operations. Such additional components 182a-182c can include, but are not limited to, bias voltage generators, reference voltage generators, temperature control circuits, etc. The particular multi-bit trim signal(s) 185a-185c can be employed by the additional component(s) 182a-182c to selectively adjust (i.e., tune) the adjustable output(s)183a-183c, respectively, in order to compensate for manufacturing process variations. Thus, the optimal values for such signals are determined post manufacture and will vary from chip to chip. However, instead of being stored externally and uploaded to the register(s) 181a-181c, the multi-bit trim signal(s)185a-185c can be stored within twin cells in the array 110 and, upon power up, can be sensed using the twin cell sensing operations described above, loaded into the registers 181a-181c from the sense amplifiers 170, and employed, for example, in subsequent sensing or other operations.

Specifically, at least one row of the memory cells 101 in the array 110 can be designated for use as twin cells for storage of the trim bits of multi-bit trim signals. Such a row can include at least one set of twin cells. Each twin cell in a set can store a single trim bit of a corresponding multi-bit trim signal. Additionally, each twin cell in the set can be located in a different group of columns within the array 110 so the bits stored in the twin cells of the set can be sensed by different sense amplifiers 170. In response to specific primary and secondary enable signals received by the switch circuits 150, the switch circuits 150 can selectively enable concurrent twin cell sensing by the sense amplifiers 170 of all the twin cells in a given set in order to output a multi-bit trim signal. For example, a first multi-bit trim signal 185a stored in a first set of twin cells in a row in the array 110 can correspond to a Vpnr trim signal to be stored in a first register 181a and subsequently used by a first gate bias voltage generator 182a to generate and adjust Vpnr 183a and to output Vpnr 183a to the sense amplifiers 170. Additionally, or alternatively, a second multi-bit trim signal 185b stored in a second set of twin cells in a row in the array 110 can correspond to a Vppr trim signal to be stored in a second register 181b and subsequently used by a second gate bias voltage generator 182b to generate and adjust Vppr 183b and to output Vppr 183b to the sense amplifiers 170. Additionally, or alternatively, a third multi-bit trim signal 185c stored in a third set of twin cells in a row in the array 110 can correspond to a third trim signal to be stored in a third register 181b and subsequently used by a third component 182c to generate, adjust, and output a third adjustable output 183c, and so on.

It should be noted that, prior to storage of the multi-bit trim signal(s) 185a-185b within the register(s) 181a-181b and, particularly, during twin cell sensing to initially read out these multi-bit trim signals(s) 185a-185b, the gate bias voltage generator(s)182a-182b can generate and output nominal gate bias voltage(s) (e.g., nominal Vpnr and nominal Vppr) to the sense amplifiers 170 to enable the sensing operations to be performed. Then, following storage of the multi-bit trim signal(s) 185a-185b in the register(s) 181a-181b, the gate bias voltage generator(s) 182a-182b can receive the multi-bit trim signal(s) 185a-185b from the register(s) 181a-181b and, based thereon, can generate and output the adjusted gate bias voltage(s) 183a-183b (e.g., adjust Vpnr and adjusted Vppr) to tune sense amplifier sensitivity during subsequent sensing operations. It should be understood that the specific adjustment amount, higher or lower, from nominal will be indicated by the multi-bit trim signal stored in the register.

The NVM structure 100 can further include one or more switches 175 at the outputs 173, respectively, of the sense amplifiers 170. Such switches 175 can be selectively controlled (e.g., by control signals from the controller or the column address decode logic 194) to ensure that the sensed data bits of each multi-bit trim signal are diverted away from primary data output paths 176 and instead are output along secondary data output paths 177 to the appropriate register for storage therein.

It should be understood that the terminology used herein is for the purpose of describing the disclosed structures and methods and is not intended to be limiting. For example, as used herein, the singular forms “a,” “an” and “the” are intended to include the plural forms as well, unless the context clearly indicates otherwise. Additionally, as used herein, the terms “comprises,” “comprising,” “includes” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure comprising:
columns of memory cells;
bitlines for the columns, wherein each bitline is connected to all memory cells in a corresponding column;
a sense amplifier; and
a switch circuit electrically connected to the bitlines for a group of the columns and to the sense amplifier, wherein the switch circuit establishes electrical connections enabling any of single cell sensing by the sense amplifier and twin cell sensing by the sense amplifier.

2. The structure of claim 1,
wherein the single cell sensing includes sensing, by the sense amplifier, of a data value stored in a single memory cell in a single column of the group, and
wherein the twin cell sensing includes sensing, by the sense amplifier, of a data value stored in two memory cells in two columns, respectively, of pair of columns in the group.

3. The structure of claim 1,
wherein the sense amplifier includes: a first input; and a second input, and
wherein the switch circuit includes:
multiple input nodes electrically connected to the bitlines, respectively, for the group;
an additional input electrically connected to a reference generator;
a first output node electrically connected to a first input of the sense amplifier; and
a second output node electrically connected to a second input of the sense amplifier.

4. The structure of claim 3, wherein, for the single cell sensing, the switch circuit establishes a first electrical connection between the first input of the sense amplifier and a single bitline of a single column within the group and further establishes a second electrical connection between the second input and the reference generator to enable a comparison, by the sense amplifier, of a data signal from a single memory cell in the single column to a reference signal from the reference generator.

5. The structure of claim 3, wherein, for the twin cell sensing, the switch circuit establishes a first electrical connection between the first input and a first bitline of a first column of a pair of columns within the group, disconnects the second input from the reference generator, and establishes a second electrical connection between the second input and a second bitline of a second column of the pair to enable a comparison, by the sense amplifier, of a true data signal from a first memory cell in the first column and a complement data signal from a second memory cell in the second column.

6. The structure of claim 3, further comprising source lines for the columns,
wherein the memory cells in any column are connected between a source line and the bitline for the column, and
wherein the memory cells comprise any of: an access transistor and a programmable resistor connected in series; and a threshold voltage-programmable transistor.

7. The structure of claim 6, wherein the switch circuit includes:
a first sense line, wherein the first output node is electrically connected to the first sense line;
a second sense line, wherein the second output node is electrically connected to the second sense line;
for each pair of columns in the group,
a first switch between a first bitline for a first column of the pair and the first sense line;
a second switch between the first bitline and the first sense line;
a third switch between a first source line for the first column and ground;
a fourth switch between the first source line of the first column and ground;
a fifth switch between a second bitline for a second column of the pair and the first sense line;
a sixth switch between the second bitline and the second sense line;
a seventh switch between a second source line for the second column and ground; and
an eighth switch between the second source line and ground; and
an additional switch between the reference generator and the second output node.

8. The structure of claim 7, wherein the first switch, the second switch, the third switch, the fourth switch, the fifth switch, the sixth switch, the seventh switch, the eighth switch, and the additional switch comprise N-channel field effect transistors.

9. The structure of claim 7,
wherein all first switches, all third switches, all fifth switches, and all seventh switches within each switch circuit are controlled by primary read mode enable signals that are column-specific,
wherein all second switches, all fourth switches, all sixth switches and all eighth switches within each switch circuit are controlled by secondary read mode enable signals that are column pair-specific, and
wherein the additional switch is controlled by an additional enable signal.

10. The structure of claim 1, wherein the group of the columns comprises an even number of columns and at least one pair of columns.

11. A structure comprising:
memory cells arranged in columns and rows;
bitlines for the columns, wherein each bitline is connected to all memory cells in a corresponding column;
sense amplifiers for groups of the columns, respectively; and
switch circuits for the groups of the columns, respectively,
wherein each switch circuit is electrically connected to the bitlines for a corresponding group of the columns and to a corresponding sense amplifier,
wherein the switch circuits establish electrical connections to enable any of two different types of sensing operations by the sense amplifiers, and
wherein the two different types of sensing operations include single cell sensing and twin cell sensing.

12. The structure of claim 11,
wherein the single cell sensing includes sensing, by the corresponding sense amplifier, of a data value stored in a single memory cell in a single column of the corresponding group by comparing a data signal from a single bitline for the single column to a reference signal, and
wherein the twin cell sensing includes sensing, by the corresponding sense amplifier, of a data value stored in two memory cells in two columns, respectively, of a pair of columns in the corresponding group by comparing a true data signal from a first bitline for a first column of the pair to a complement data signal from a second bitline for a second column of the pair.

13. The structure of claim 11,
wherein at least one row of the memory cells includes a set of twin cells with each twin cell in the set being in a different group of the groups of the columns and storing a single bit of a multi-bit trim signal, and
wherein, in response to specific primary and secondary enable signals received by the switch circuits upon power up, the switch circuits enable concurrent twin cell sensing by the sense amplifiers of all the twin cells in the set to output the multi-bit trim signal.

14. The structure of claim 13, further comprising a register, wherein the register receives the multi-bit trim signal from the sense amplifiers and stores the multi-bit trim signal.

15. The structure of claim 14, wherein the structure further comprises an additional component having an adjustable output, wherein the additional component adjusts the adjustable output based on the multi-bit trim signal, and wherein the adjustable output is employed by the structure during subsequent operations.

16. The structure of claim 15, wherein the additional component comprises a bias voltage generator connected to the sense amplifiers, and wherein the bias voltage generator outputs an adjustable bias voltage to the sense amplifiers.

17. The structure of claim 16,
wherein, prior to storage of the multi-bit trim signal in the register, the bias voltage generator outputs a nominal gate bias voltage, and
wherein, following storage of the multi-bit trim signal in the register, the bias voltage generator receives the multi-bit trim signal from the register and based on the multi-bit trim signal, outputs an adjusted gate bias voltage to the sense amplifiers to tune sense amplifier sensitivity.

18. The structure of claim 11, further comprising source lines for the columns, wherein the memory cells in any column are connected between a source line and the bitline for the column, and wherein the memory cells comprise any of: an access transistor and a programmable resistor connected in series; and a threshold voltage-programmable transistor.

19. The structure of claim 11, wherein each group of the columns comprises an even number of at least two columns.

20. A structure comprising:
memory cells arranged in columns and rows;
bitlines for the columns, wherein each bitline is connected to all memory cells in a corresponding column;
sense amplifiers for groups of the columns, respectively;
switch circuits for the groups of the columns, respectively, wherein each switch circuit is electrically connected to the bitlines for a corresponding group of the columns and to a corresponding sense amplifier; and
a column decoder in communication with the switch circuits,
wherein the column decoder outputs primary and secondary read mode enable signals to the switch circuits,
wherein, depending upon the primary and secondary read mode enable signals, the switch circuits establish electrical connections to enable any of two different types of sensing operations by the sense amplifiers, and
wherein the two different types of sensing operations include single cell sensing and twin cell sensing.
